(19) United States
(12) Patent Application Publication
(10) Pub. No.: US 2024/0385508 A1
(43) Pub. Date: Nov. 21, 2024

(54) ENHANCED ULTRA-THIN, ULTRA-LOW DENSITY FILMS FOR EUV LITHOGRAPHY AND METHOD OF PRODUCING THEREOF

(71) Applicant: LINTEC OF AMERICA, INC., Plano, TX (US)

(72) Inventors: Marcio D. LIMA, Richardson, TX (US); Takahiro UEDA, Frisco, TX (US)

(73) Assignee: LINTEC OF AMERICA, INC., Plano, TX (US)

(21) Appl. No.: 18/695,933

(22) PCT Filed: Sep. 27, 2022
(86) PCT No.: PCT/US2022/044908

§ 371 Date: Mar. 27, 2024

Related U.S. Application Data
(60) Provisional application No. 63/249,113, filed on Sep. 28, 2021.

(51) Int. Cl. G03F 1/62

(52) U.S. Cl. CPC G03F 1/62

(57) ABSTRACT

A filtration formed nanostructure pellicle film is disclosed. The filtration formed nanostructure pellicle film includes a plurality of carbon nanofibers that are intersected randomly to form an interconnected network structure in a planar orientation with enhanced properties by plasma treatment. The interconnected structure allows for a high minimum EUV transmission rate of at least 92%, with a thickness ranging from a lower limit of 3 nm to an upper limit of 100 nm, to allow for effective EUV lithography processing.

### CROSS-REFERENCE TO RELATED APPLICATION

This application claims priority to U.S. Provisional Patent Application No. 63/249, 113, filed Sep. 28, 2021. The disclosure of each of these documents, including the specification, drawings, and claims, is incorporated herein by reference in its entirety.

### TECHNICAL FIELD

This disclosure generally relates to a thin film and thin film device used in a semiconductor microchip fabrication and, more particularly, to an ultra-thin, ultra-low density, nanostructured free-standing pellicle film with enhanced mechanical properties for extreme ultraviolet (EUV) lithography and a production method of such pellicles and pellicle films.

### BACKGROUND

A pellicle is a protective device. The pellicle covers a photomask and is used in semiconductor microchip fabrication. The photomask may refer to an opaque plate with holes or transparencies that allow light to shine through in a defined pattern. Such photomasks may be commonly used in photolithography and the production of integrated circuits. As a master template, the photomask is used to produce a pattern on a substrate, normally a thin slice of silicon known as a wafer in the case of semiconductor chip manufacturing.

Particle contamination can be a significant problem in semiconductor manufacturing. A photomask is protected from particles by a pellicle; a thin transparent film stretched over a frame that is attached over the patterned side of the photomask. The pellicle is close but far enough away from the mask so that moderate-to-small-sized particles that land on the pellicle will be too far out of focus to print. Recently, the microchip manufacturing industry realized that the pellicle might also protect the photomask from damage stemming from causes other than particles and contaminants.

Extreme ultraviolet lithography is an advanced optical lithography technology using a range of EUV wavelengths, more specifically, a 13.5 nm wavelength. It enables semiconductor microchip manufacturers to pattern the most sophisticated features at 7 nm resolution and beyond and put many more transistors without increasing the size of the required space. EUV photomasks work by reflecting light, which is achieved by using multiple alternating layers of molybdenum and silicon. When an EUV light source turns on, the EUV light hits the pellicle film first, passes through the pellicle film, and then bounces back from underneath the photomask, hitting the pellicle film once more before it continues its path to print a microchip. Some of the energy is absorbed during this process, and heat may be generated, absorbed, and accumulated as a result. The temperature of the pellicle may heat up to anywhere from 600 to 1000° Celsius or above.

While heat resistance is important, the pellicle must also be highly transparent for EUV light to ensure the passing through of the reflected light and light pattern from the photomask.

In 2016, a polysilicon-based EUV pellicle was developed after decades of research and effort with only 78% EUV transmission on a simulated relatively low-power 175-watt EUV source. Due to greater transistor density demand, stringent requirements present further technical challenges to EUV pellicle developers for a higher transmission rate, lower transmission variation, higher temperature tolerance, and strong mechanical strength.

Attempts have been made to target a higher EUV transmittance rate (e.g., 90%, 95% or even 98%) by deploying carbon nanotubes (CNTs) into the formation of pellicle films. However, for producing and utilizing a thin film with the higher EUV transmittance in an EUV lithography scanner chamber, further enhancement of the film's mechanical strength is required as any pressure disturbance or mechanical vibration during product packaging, freight, and scanner pump-down and venting may cause unrepairable breakage of films. Accordingly, existing technology is unable to produce and provide a pellicle film with high EUV transmittance rates with sufficient mechanical strength for use in the EUV lithography scanner.

Furthermore, the demand for a notably larger film size for EUV scanners, e.g., a full-size pellicle film of 110 mm by 140 mm or above on a larger border presents additional challenges concerning the mechanical strength requirement while maintaining the ultra-thin and high EVU transmission status.

Therefore, in conventional technology, featuring three factors of high transmittance of EUV light, ultra-thin thickness of the pellicle film, and strong mechanical strength in one embodiment, which are often self-conflicting, constrains the development of EUV pellicles significantly.

Existing methods of increasing membrane film strength are ineffective in producing such a thin film.

### SUMMARY

According to an aspect of the present disclosure, a specifically structured nanotube film is disclosed. The nanotube film includes a plurality of carbon nanotubes that are intersected randomly to form an interconnected network structure in a planar orientation, the interconnected network structure having a thickness ranging from a lower limit of at least 3 nm to an upper limit of at most 100 nm, and a minimum EUV transmission rate of 92% or above.

According to another aspect of the present disclosure, in some embodiments, a thickness ranges between the lower limit of 3 nm to the upper limit of 40 nm.

According to another aspect of the present disclosure, in some embodiments, a thickness ranges between the lower limit of 3 nm to the upper limit of 20 nm.

According to yet another aspect of the present disclosure, in some embodiments, an average thickness of the interconnected network structure is between 10.7 nm and 11.9 nm.

According to a further aspect of the present disclosure, in some embodiments, an EUV transmission rate rises to above 95%.

According to yet another aspect of the present disclosure, in some embodiments, an EUV transmission rate rises to above 98%.

According to a further aspect of the present disclosure, the plurality of carbon nanotubes further includes single-walled carbon nanotubes and multi-walled carbon nanotubes. A number of walls of single-walled carbon nanotubes is one, a number of walls of the double-walled carbon nanotubes is two, and a number of walls of the multi-walled carbon nanotubes is three or more.

According to another aspect of the present disclosure, the single-walled carbon nanotubes account for a percentage between 20-40% of all carbon nanotubes, double-walled carbon nanotubes account for a percentage of 50% or higher of all carbon nanotubes, the remaining carbon nanotubes are multi-walled carbon nanotubes.

According to a further aspect of the present disclosure, the nanotube film is further treated by a plasma treatment.

According to a further aspect of the present disclosure, the plasma treatment of nanostructure films selects a gas from hydrogen or oxygen.

According to another aspect of the present disclosure, a pellicle undergoes a plasma treatment.

According to another aspect of the present disclosure, the plasma treatment of pellicles applies an active gas selected from oxygen, hydrogen, or atmospheric air.

According to another aspect of the present disclosure, the plasma treatment is mild as defined by a treatment time interval, treatment power, and a type of gas.

According to a further aspect of the present disclosure, the treatment time interval is between 1 to 60 seconds, with a preferred treatment time interval between 5 to 20 seconds.

According to one aspect of the present disclosure, the plasma treatment applies an power between 15 watts and 35 watts.

According to a further aspect of the present disclosure, the plasma treatment power is between 15 watts and 20 watts.

According to one aspect of the present disclosure, the plasma treatment of a small size 10 mm×10 mm pellicle film may be in the range of 15 watts to 35 watts with a treatment time interval not exceeding 50 seconds.

According to another aspect of the present disclosure, the plasma treatment of a small size 10 mm×10 mm pellicle film may be preferably in the range of 15 watts to 20 watts with a treatment time interval between 5 to 20 seconds.

According to one aspect of the present disclosure, a plasma treatment applies an power of 15 to 25 watts for a full-size or larger pellicle film.

According to another aspect of the present disclosure, the plasma treatment applies an power of 22 watts or less for a full-size or larger pellicle film.

According to another aspect of the present disclosure, a plasma treatment applies a 10 to 20 watts power for a full-size or larger ultra-thin pellicle film with a 550 nm light transmittance greater than 89%.

According to another aspect of the present disclosure, a plasma treatment applies a 15 or 16 watts power for a full-size or larger ultra-thin pellicle film with a 550 nm light transmittance greater than 89%.

According to one aspect of the present disclosure, the plasma treatment time interval is 25 seconds or less for a full-size pellicle film.

According to another aspect of the present disclosure, the plasma treatment time interval is 22 seconds or less for a full-size pellicle film.

According to another further aspect of the present disclosure, the plasma treatment time interval is 6-15 seconds for a full-size or larger ultra-thin pellicle film with a 550 nm light transmittance greater than 89%.

According to yet another further aspect of the present disclosure, the plasma treatment time interval is 6-15 seconds for a full-size or larger ultra-thin pellicle film with a 550 nm light transmittance greater than 89%.

According to one further aspect of the present disclosure, the plasma treatment time interval is 6 seconds or 10 seconds for a full-size or larger ultra-thin pellicle film with a 550 nm light transmittance greater than 89%.

### BRIEF DESCRIPTION OF THE DRAWINGS

The present disclosure is further described in the detailed description which follows, in reference to the noted plurality of drawings, by way of non-limiting examples of preferred embodiments of the present disclosure, in which like characters represent like elements throughout the several views of the drawings.

FIG. 1 illustrates a flow chart of producing a plasma-treated nanotube pellicle film in accordance with an exemplary embodiment.

FIG. 2 illustrates a scanning electron microscope (SEM) image of a microstructure of an untreated CNT film in accordance with an exemplary embodiment.

FIG. 3 illustrates a time-course study result of plasma treatment vs. average light transmission measured at 550 nm wavelength for oxygen plasma-treated 10 mm×10 mm films, as well as the average percentage change of light transmission in accordance with an exemplary embodiment.

FIG. 4 illustrates a time-course study result of plasma treatment vs. average light transmission measured at 550 nm wavelength for hydrogen-treated 10 mm×10 mm films, as well as the average percentage change of light transmission in accordance with an exemplary embodiment.

FIG. 5 illustrates a time-course study result of plasma treatment vs. film deflections measured at 2 Pascal constant pressure for oxygen plasma-treated 10 mm×10 mm films in accordance with an exemplary embodiment.

FIG. 6 illustrates a time-course study result of plasma treatment vs. film deflections measured at 2 Pascal constant pressure for hydrogen plasma-treated 10 mm×10 mm films in accordance with an exemplary embodiment.

FIG. 7 illustrates a time-course study result of plasma treatment vs. measured film rupture pressures for oxygen plasma-treated films in accordance with an exemplary embodiment.

FIG. 8 illustrates a time-course study result of plasma treatment vs. measured film rupture pressures for hydrogen plasma-treated samples in accordance with an exemplary embodiment.

FIG. 9 illustrates a time-course study of plasma treatment vs. film rupture flow rate for oxygen plasma-treated nanotube films in accordance with an exemplary embodiment.

FIG. 10 illustrates a time-course study of plasm treatment vs. film rupture flow rate for hydrogen plasma-treated nanotube films in accordance with an exemplary embodiment.

### DETAILED DESCRIPTION

Through one or more of its various aspects, embodiments and/or specific features, sub-components, or processes of the present disclosure, are intended to bring out one or more of the advantages as specifically described above and noted below.

A pellicle may refer to a thin transparent film that protects a photomask during semiconductor microchip production. The pellicle contemplates a protective device with a border frame and a central aperture. Both border and aperture are covered by a continuous thin film on the top of at least a portion of the border and the entire aperture. The center portion of such a thin film over the aperture is free-standing. The pellicle may act as a dust cover that prevents particles and contaminants from falling onto the photomask during production. However, the pellicle must be sufficiently transparent to allow the transmission of EUV light for performing lithography. A higher level of light transmission is desired for more effective lithography.

Further, pellicles for EUV lithography require a large (e.g., greater than 110×140 mm) free-standing, thin-film material with extreme and unique properties. A full-size EUV pellicle may refer to a pellicle device with a free-standing film covering a 110 mm×140 mm aperture or larger.

Besides high transparency to EUV radiation, the pellicle needs to be resistant to temperatures above 600° C. and mechanically robust to survive handling, shipping, pumping down, and venting operations during the photolithographic process. Gas permeability but with a capacity to retain micrometer-size particles is also desired. Given the number of high-level properties required, effective EUV pellicles have been conventionally difficult to produce.

In this aspect, carbon nanotubes have been suggested as a possible starting material to create pellicles for this EUV pellicle application due to their excellent thermal and mechanical properties and capability to form porous films.

### Carbon Nanotubes and Carbon Nanotube Films

Carbon nanotubes (CNTs) generally have several different types, including, without limitation, single-walled CNTs (SWCNTs), double-walled CNTs (DWCNTs), multi-walled CNTs (MWCNTs), and coaxial nanotubes. They may exist substantially pure in one type or often in combination with other types. An individual CNT may be intersected with a few others. Together, many CNTs could form a mesh-like free-standing microstructure thin film. As the name suggests, SWCNTs have one or single wall, DWCNTs have two walls, and MWCNTs have three or more walls.

Further, among several possible methods to fabricate free-standing films, a filtration-based approach was utilized to produce films from small-size films to sufficiently large and uniform films for EUV lithography or even larger than the full-size pellicles. This filtration-based method allows for quick manufacturing of films not only of CNTs but also other high aspect ratio nanoparticles and nanofibers such as boron nitride nanotubes (BNNT) or silver nanowires (AgNW). Since this approach separates the nanoparticle synthesis method and the film manufacturing method, a variety of types of nanotubes produced by virtually any method may be used. Different types of nanotubes can be mixed in any desired ratio, such as a mixture of two or more CNTS selected from SWCNT, DWCNTs, and MWCNTs. As filtration is a self-leveling process in the sense that non-uniformities of film thickness during the filtration process are self-corrected by the variations of local permeability and, therefore, a highly desirable film formation process, it is also a promising candidate for the production of highly uniform films.

After film formation, a plasma treatment is applied to the pellicle film, which is on a pellicle border or a carrying frame, with a selected gas and a plasma treatment time interval to strengthen the mechanical properties of the films, reduce the film deflection, and increase film rupture pressure and flow rate when the film ruptures.

Plasma treatment is widely used to clean, activate, etch, and coat surfaces of materials in various technology fields for different purposes. The different purposes includes promoting surface adhesion, wettability, and hydrophilicity. A lower power plasma treatment, as low as 100 watts for 10 seconds, to a stack of polyvinyl alcohol densified 100-layer CNT sheets drawn from CNT forests has shown improvement of d Young's modulus and tensile strength as tested by Surfx Atomflo™ 400 plasma system, while a higher power treatment, such as 140 watts for 30 seconds, actually reduced sheets' Young's modulus and tensile strength.

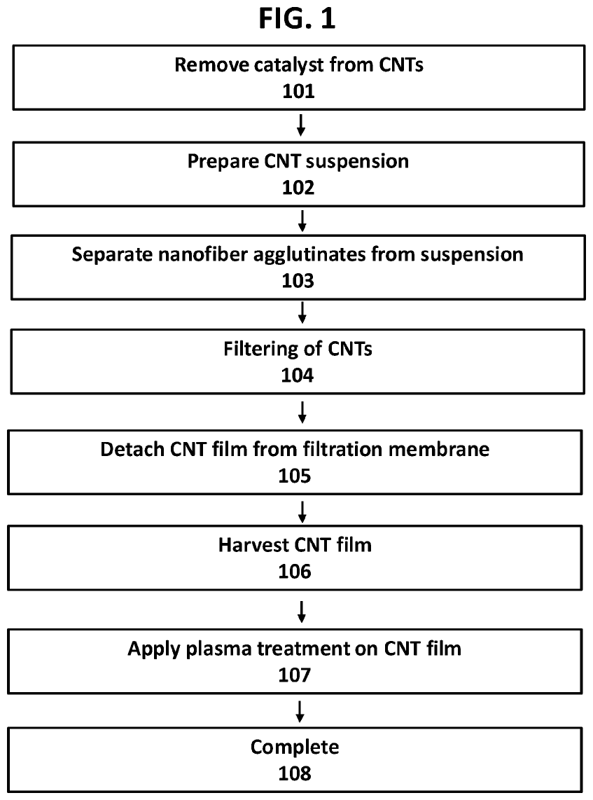

FIG. 1 illustrates a flow chart of producing a plasma-treated nanotube pellicle film in accordance with an exemplary embodiment.

As illustrated in FIG. 1, a free-standing carbon nanotube-based pellicle film may be produced via a filtration-based method. In operation 101, catalysts are removed from carbon nanotubes (CNTs) that are to be used to form a water-based suspension. In an example, prior to dispersion into a suspension, the CNTs may be chemically purified to reduce a concentration of catalyst particles to less than 1% or preferably less than 0.5% wt. as measured by thermogravimetric analysis. Removal of the catalyst is not limited to any particular process or procedure, such that any suitable process may be utilized to achieve a desirable result.

In operation 102, a water-based suspension is prepared using the purified CNTs, such that the purified CNTs are evenly dispersed in water. When preparing one or more CNT suspensions, carbon nanotube material may be mixed with a selected solvent to uniformly distribute nanotubes in a final solution as a suspension. Mixing can include mechanical mixing (e.g., using a magnetic stir bar and stirring plate), ultrasonic agitation (e.g., using an immersion ultrasonic probe) or other methods. In some examples, the solvent can be a protic or aprotic polar solvent, such as water, isopropyl alcohol (IPA), and aqueous alcohol mixtures, e.g., 60, 70, 80, 90, 95% IPA, N-Methyl-2-pyrrolidone (NMP), dimethyl sulfide (DMS), and combinations thereof. In an example, a surfactant may also be included to aid the uniform dispersion of carbon nanofibers in the solvent. Examples of surfactants include, but are not limited to, anionic surfactants.

Carbon nanofiber films are generally formed from one of MWCNTs, DWCNTs, or SWCNTs. A carbon nanofiber film may also include a mixture of two or more types of CNTs (i.e., SWCNTs, DWCNTs, and/or MWCNTs) with a variable ratio between the different types of CNTs.

Each of these three different types of carbon nanotubes (MWCNT, DWCNT, and SWCNT) has different properties. In one example, single wall carbon nanotubes can be more conveniently dispersed in water or water with a solvent (i.e., with the majority of nanotubes suspended individually and not adsorbed onto other nanotubes) for subsequent formation into a sheet of randomly oriented carbon nanotubes. This ability of individual nanotubes to be uniformly dispersed in water or water with a solvent can, in turn, produce a more planarly uniform nanotube film formed by removing the water and solvent from the nanofiber suspension. This physical uniformity can also improve the uniformity of the properties across the film (e.g., even irradiation transmission to a film).

As used herein, the term “nanofiber” means a fiber having a diameter less than 1 μm. As used herein, the terms “nanofiber” and “nanotube” are used interchangeably and encompass both single wall carbon nanotubes, double wall carbon nanotubes and/or multiwall carbon nanotubes in which carbon atoms are linked together to form a cylindrical structure.

In an example, the initially formed water-based CNT suspension in operation 102 may have at least above 85% purity of SWCNTs. The remaining may be a mixture of DWCNTs, MWCNTs and/or a catalyst. In other examples, a dispersed CNT suspension with various ratios of different types of CNTs may be prepared, such as about 20%/75% DWCNTs/SWCNTs, about 50%/45% DWCNTs/SWCNTs, about 70%/20% DWCNTs/SWCNTs, with MWCNTs accounted for the remaining. In an example, anionic surfactants may be utilized as the catalyst in the suspension.

In operation 103, the CNT suspension is then further purified to remove the aggregated or agglutinated CNTs from the initial mixture. In an example, different forms of CNTs, undispersed or aggregated vs. fully dispersed, may be separated from the suspension via centrifugation. Centrifugation of surfactant-suspended carbon nanotubes may aid in decreasing the turbidity of the suspension solution and ensuring a full dispersion of the carbon nanotubes in the final suspension solution before going into the next filtration step. However, aspects of the disclosure are not limited thereto, such that other separation methods or processes may be utilized.

In operation 104, the CNT supernatant from operation 103 is then filtered through a filtration membrane to form a CNT web, a continuous sheet of film of intersecting CNTs.

In an example, one technique for making the CNT film uses water or other fluids to deposit nanotubes in a random pattern on a filter. The evenly dispersed CNT-containing mixture is allowed to pass through or is forced to pass through the filter, leaving nanotubes on the surface of the filter to form a nanotube structure or a film. The size and shape of the resulting film are determined by the size and shape of the desired filtration area of the filter, while the thickness and density of the films are determined by the quantity of nanotube material utilized during the process and the permeability of the filtration membrane to the ingredients of the input CNT material, as the impermeable ingredient is captured on the surface of the filter. If the concentration of nanotubes dispersed in the fluid is known, the mass of nanotubes deposited onto the filter can be determined from the amount of fluid that passes through the filter, and the film's average areal density is determined by the nanotube mass divided by the total filtration area. The selected filter is generally not permeable to any CNTs.

The filtration formed CNT film may be of a combination of SWCNT, DWCNT, and/or MWCNT in differing compositions.

In operation 105, the CNT film is then detached from the filtration membrane. More specifically, carbon nanofibers may become intersected randomly to form an interconnected network structure in a planar orientation to form the thin CNT film.

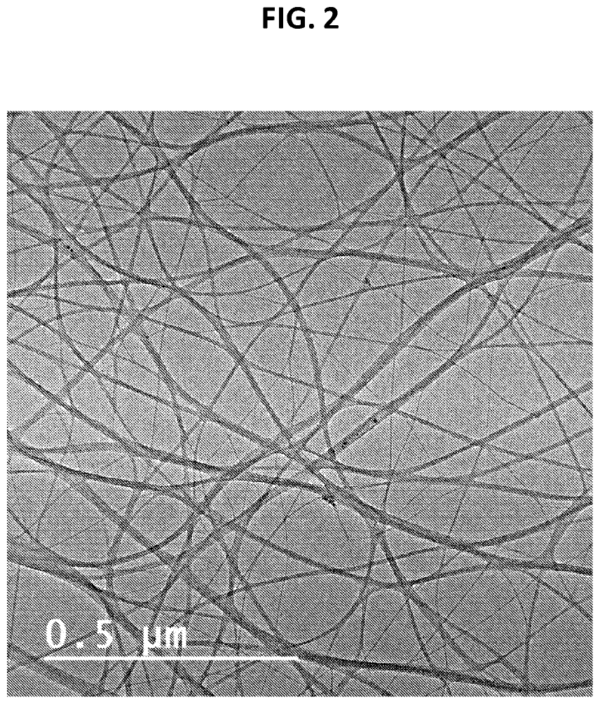

In operation 106, the lifted CNT film is then harvested using a harvester frame and then directly transferred and mounted onto virtually any solid substrate, such as a pellicle border with a defined aperture. The CNT film may be mounted to the pellicle border and cover the aperture to form a pellicle. The transferred film mounted on a metal frame or silicon frame with an opening of as small as 1×1 cm may be useful. A much larger size film is in high demand for an actual EUV scanner. A scanning electron microscope (SEM) image of a CNT film prepared according to FIG. 1 is illustrated in FIG. 2 in accordance with an exemplary embodiment. A full-size pellicle for EUV lithography scanning may require an ultra-thin, free-standing film generally in a size of 110×140 mm, based on current industry standard, or larger.

CNT films are further treated by plasma in operation 107. A plasma treatment uses a selected active gas or gas precursor with a predetermined treatment power and a treatment time interval. Many gases may be considered and applied to generate plasma. The plasma treatment power and treatment time interval vary according to actual applications. Upon completion of operation 107, the method for producing a plasma-treated nanotube pellicle film is completed in operation 108.

With or without plasma treatment, CNT film characterization, such as its mechanical strength, deflection test, permeability test, deflection at constant pressure, or during pumping down conditions, may be performed.

Exemplary embodiment of the present disclosure provides a filtered CNT pellicle film having a different constitution from known prior art for exhibiting properties meeting or exceeding certain aspects of EUV lithography requirements, including, but not limited to, EUV transmittance (EUVT), EUVT evenness, low deflection, and mechanical strength under pressure changes.

This exemplary constitution of the pellicle film provides an ultra-thin pellicle film, which allows for very high EUVT (e.g., greater than 92%, 95%, or even 98%) while being extremely temperature resistant (e.g., resistant to temperatures above 600° C.) and mechanically robust. In an example, a minimum EUVT may be a value of 92% or greater.

Although the above-noted disclosure was provided with respect to CNTs and water solution, aspects of the present disclosure are not limited thereto, such that different nanotubes, such as boron nitride nanotubes (BNNT), may be utilized by the same principle.

The above-mentioned thin films may also be conformally coated by various methods, including, without limitation, e-beam, chemical vapor deposition, atomic layer deposition, spin coating, dip coating, spray coating, sputtering, DC sputtering, and RF sputtering. The material may be a metal element including any one of the following, silicon, SiO₂, SiON, boron, ruthenium, boron, zirconium, niobium, molybdenum, rubidium, yttrium, YN, Y₂O₃, strontium, and/or rhodium. The material may also be any one of a metal, metal oxides or nitrides. However, aspects of the present disclosure are not limited thereto, such that a combination of materials may be used in the coating.

### Plasma Treatment

Plasma treatment is a known technique used in various scientific and technical fields and manufacturing processes. It is generally used for surface cleaning, activations, hydrophilicity alteration, etching, or preparation for subsequent bonding of other materials with different combinations of active gases, gas precursors, gas mixtures, treatment energies, and treatment time intervals. Plasma treatment with one or more inadequate parameters, either under optimal or over optimal conditions, may generate dissatisfactory results on the target surfaces or cause irreversible damage to the targets or target surfaces, including the ruin of targets or target surfaces. Effective treatment upon any surface may also be specified or specifically tuned.

In an exemplary embodiment of the present disclosure, a pellicle is placed in a 25 cm×25 cm enclosure or chamber. Then, the chamber is closed and purged with oxygen, hydrogen, nitrogen gas, or atmospheric air at a low rate of 25 sccm (cubit centime per second) due to the high pressure and gas flow sensitivities of the ultra-thin nanotube films. In an example, the plasma treatment may be performed in a low-pressure environment, such as 0.2-0.3 Pascals, and the treatment temperature may be a room or ambient temperature. Further, a radio frequency power in a range between 1-100 watts is applied for 1-600 seconds. The chamber may then ventilate slowly, from 5 minutes to overnight, and remove the sample.

Multiple samples were prepared for each testing groups, and multiple measurements of the same sample were performed.

### Thin Film Thickness

An exemplary embodiment of the present disclosure is further analyzed for its thickness which is critical to determine and ensure a high EUVT. More specifically, a Dimension Icon AFM instrument was calibrated first against a National Institute of Standards and Technology (NIST) traceable standard. An area of approximately 90 μm×90 μm of CNT pellicle film was selected for AFM 2D and 3D height imaging. Step height analyses were performed to measure the film thickness. Three measurements from three carbon nanotube film samples were taken with readings of 11.8 nm, 10.6 nm, and 11.4 nm, respectively. The average thickness of the testing subject was about 11.3±0.6 nm (10.7 nm-11.9 nm).

Further, based on additional measurement sets, thickness values ranging from 3 nm to 100 nm, from 3 nm to 40 nm, and from 3 nm to 20 nm were provided.

In addition, thickness values may also range from 3 nm to 100 nm, from 3 nm to 40 nm, and from 3 nm to 20 nm in other samples. However, aspects of the present application are not limited thereto, such that a range may have a lower-end value of 3 nm to 5 nm, and an upper-end value of 20 nm to 100 nm.

Given the much higher mechanical strength exhibited by the DWCNT dominant CNT pellicle film, the DWCNT dominant CNT pellicle film may be structured to be extremely thin, to allow for higher EUVT values without sacrificing mechanical strength or integrity for use in an EUV scanner.

### Visible Light and EUV Transmittance

The EUV transmittance of the sample was measured with the current industry standard of 13.5 nm wavelength. A EUVT map was created based on the EUV scanning results to demonstrate and measure variation and/or uniformity of the transmittance.

The filtration-formed CNT pellicle film exhibits a high EUV transmission rate, generally above 92%, with results above 95% or beyond 98% in some instances. For example, an across sample scan of a full-size pellicle film (about 110 mm×144 mm) demonstrates an average 96.69±0.15% transmission rate, while scanning the 1.5 mm×1.5 mm center region yields an average 96.75±0.03% transmission rate.

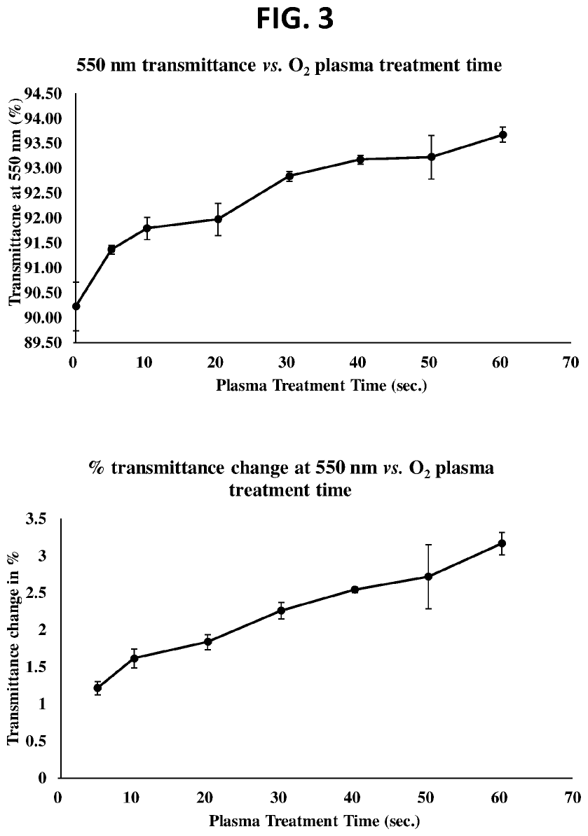

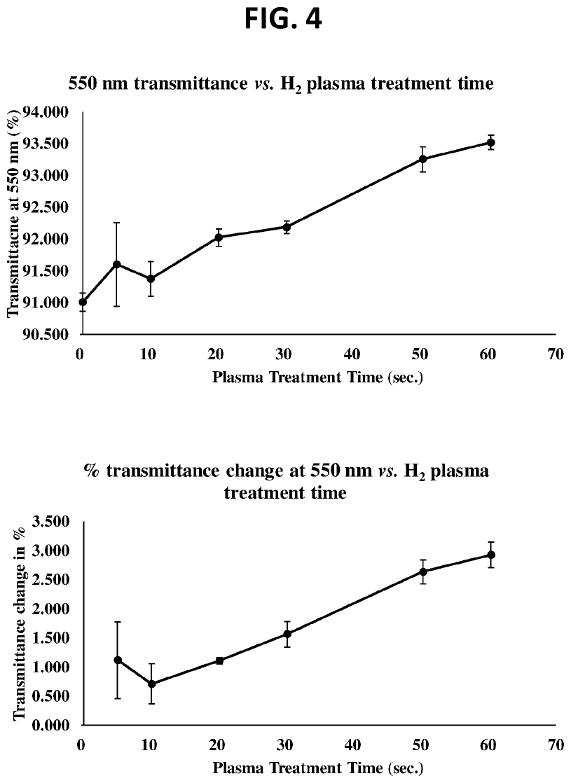

The plasma-treated pellicle films (film size: 10 mm×10 mm) are measured for their light transmittance at 550 nm and compared to the untreated negative control. The transmittances for both oxygen and hydrogen-treated films are improved. The percentages of improvement range from about 0.8% up to about 3%, as shown in FIGS. 3 and 4. This improvement correlates well to a treatment time ranging from 5 seconds to 60 seconds (see e.g., FIGS. 3 and 4).

Visible light and EUV transmittance of post-plasma treated pellicle films with the size of 110 cm×140 mm or above may be measured by the same methodology. The 15-watt oxygen plasma-treated full-size pellicle films have 1.4% and 1.7% visible light transmittance improvement at the treatment time interval of 6 seconds and 8 seconds, respectively.

### Mechanical Properties of the CNT Pellicle for EUV Lithography

Exemplary embodiments of the present application provide CNT pellicles with sufficient and satisfactory mechanical strength for product transportation and handling. The pellicles may sustain any desired pressure changes surrounding their application environment, including, but not limited to, an EUV lithography scanner environment.

A commonly applied mechanical characterization was a bulge test to measure film deflections upon a flow pressure. For example, a film for testing may be attached onto the flat surface of a border (a pellicle film mounted onto a pellicle border), and a baseline of the film without any air or gas flow impact on the film may be established. Then, an initial stream of gas, preferably inert gas, may be applied at low steady pressure aiming perpendicularly at the center region of the film to raise the local surface. The gas pressure continues to increase incrementally to deform the film further until the pressure reaches a predetermined value, which is 2 Pascal for a 2 Pa deflection test. This value may also be under a flow rate of about 10 sccm, under 3.5 mbar/second, or any scanner pump down or venting conditions. A distance between the highest tip of the deformed film and its baseline may be measured. The result may be recorded as the deflection at 2 Pa. Deflection tests may be performed at different pressures, other than 2 Pa.

Increasing the applied gas flow pressure may eventually burst the film. This pressure may be recorded as a rupture pressure, and the film deflection just before its rupture may be referred to as a rupture deflection. The gas flow rate at the time of film ruptures may be taken and referred to as rupture flow rate. Furthermore, a thin film deflection may be purposely adjusted by methods, including, but not limited to, tension adjustment by physical means or chemical means.

### Plasma Surface Treatment and Enhanced Mechanical Properties

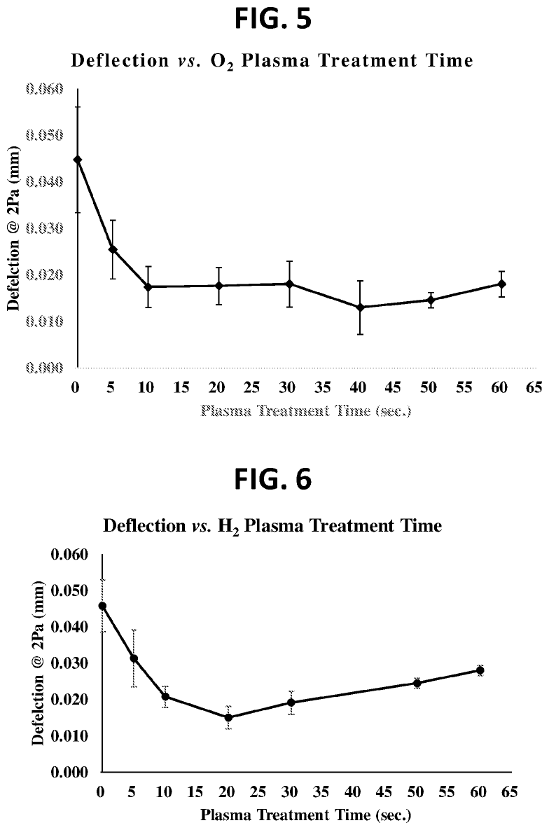

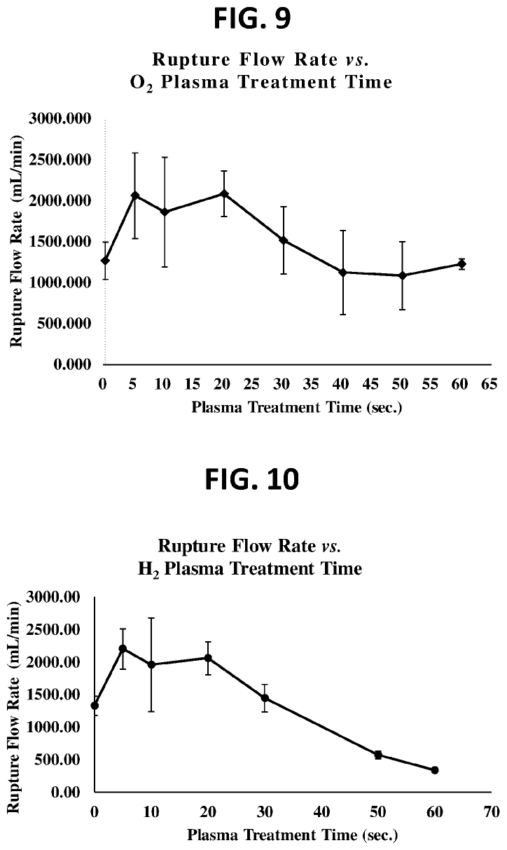

One or more exemplary embodiments of the present disclosure are detailed below and presented in FIGS. 5-10.

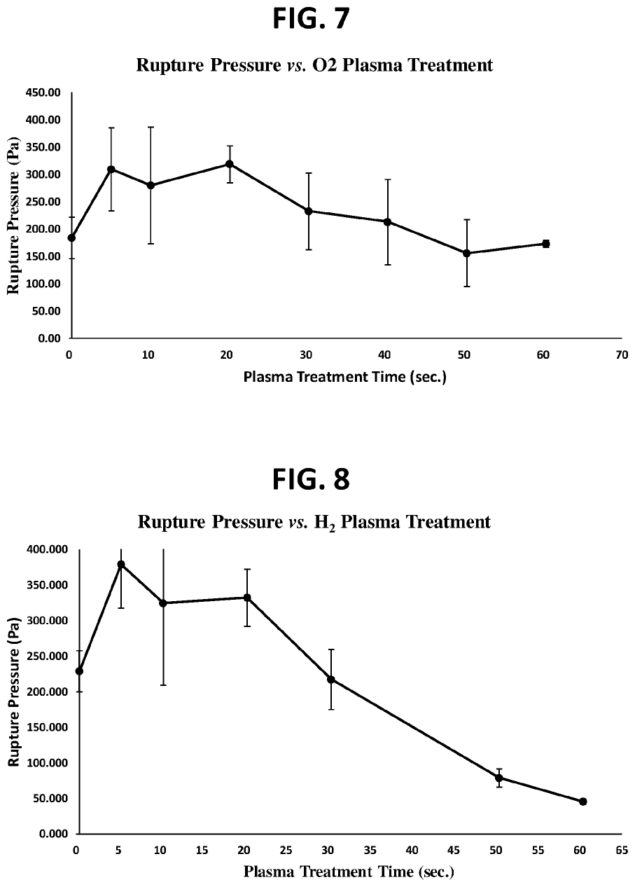

FIGS. 5-10 exemplarily present mechanical property changes of 10 mm×10 mm nanotube films after plasma treatment with either oxygen or hydrogen with various treatment times from 5 seconds to 60 seconds with a 20-watt radio frequency (RF) power in accordance with an exemplary embodiment. According to exemplary aspects, the 10 mm×10 mm films demonstrate reduced deflection with a constant 2 Pa flow challenge with short treatment time intervals. The 10 mm×10 mm films rupture at higher flow pressures and higher flow rates. Furthermore, both oxygen and hydrogen treatments of 10 mm×10 mm film reduce film deflection by more than 100% on average for a 10-second treatment, as shown in FIGS. 5 and 6, and increase rupture pressures and rupture flow rates for a 5-second treatment by more than 60% on average, as shown in FIGS. 7-10. As exemplarily illustrated, the plasma treatment benefits with respect to rupture pressure diminish beyond the 30-second treatment time interval.

Studies of smaller or larger RF powers are summarized in Table 1 below.

TABLE 1

| | | | Percentage of | Percentage of | |
|---|---|---|---|---|---|
| | | | Transmittance | Film | Change of Film |
| RF | Treatment | Treatment | Gain @ 550 nm | Deflection | Rupture Pressure |
| Power | Time | Survivability | (%) | Reduction (%) | (%) |
| 15 | 8 | Survived | 1.0 | −64.8 | 53.0 |
| 20 | 8 | Survived | 1.8 | −64.0 | 2.6 |
| 25 | 8 | Survived | 2.6 | −54.5 | −44.9 |
| 30 | 8 | Survived | 3.2 | −41.0 | −57.1 |
| 35 | 8 | Survived | 3.6 | −33.1 | −77.2 |
| 40 | 8 | Broke during | — | — | — |
| | | venting | | | |
| 50 | 8 | Broke during | — | — | — |
| | | venting | | | |

A set of 10 mm×10 mm nanotube films were subjected to a constant oxygen plasma treatment time of 8 seconds, with different RF power levels. A 20-watt treatment result shows a similar film deflection reduction and gains of rupture pressure and light transmittance measured at 550 nm when compared to previous studies of film density or percentage of transmittance at 550 nm. A higher power treatment, 25 watts or above as exemplarily illustrated in Table 1, showed film deflection reduction while the films become more brittle due to dramatic reversal of the film rupture pressure. The films became so fragile when treated with an RF power of 40-watt or above that they failed to survive the plasma treatment.

For full-size ultra-thin pellicle films, a series of plasma treatments with different active gases, different plasma power, and various treatment time intervals are detailed below and in Table 2.

TABLE 2

| | | | | Percentage | |
|---|---|---|---|---|---|
| | | | | of Trans- | Percentage |
| | RF | Treatment | | mittance | of Film |
| Gas | Power | Time | Treatment | Gain @ | Deflection |
| Type | (watts) | (sec.) | Survivability | 550 nm (%) | Reduction (%) |
| O₂ | 15 | 6 | Survived | 1.4 | −20.4 |
| O₂ | 15 | 8 | Survived | 1.7 | −23.0 |
| O₂ | 15 | 10 | Broke during | — | — |
| | | | venting | | |
| O₂ | 18 | 6 | Broke during | — | — |
| | | | venting | | |
| O₂ | 20 | 6 | Broke during | — | — |
| | | | venting | | |
| N₂ | 18 | 6 | Survived | −0.3 | −9.5 |
| N₂ | 20 | 6 | Survived | −0.2 | −9.9 |
| H₂ | 16 | 10 | Survived | 0.0 | −3.3 |
| Air | 15 | 6 | Survived | 1.4 | −20.3 |

Guided by the study results of the 10 mm×10 mm films, the full-size ultra-thin pellicles take two different paths with respect to the oxygen plasma treatment. From Table 2, they did not survive well with the even reduced plasma treatment power and treatment time interval. They broke easily after 6-second treatments under 18-watt or 20-watt applied power. A 10-second oxygen plasma treatment with 15-watt power did not save the ultra-thin film from its breakage before the completion of the treatment process. However, a 6-second and an 8-second oxygen plasma treatment with 15-watt power kept the films intact with increases in light transmission at the wavelength of 550 nm, about 1.4% and 1.7%, respectively, while the film deflections were reduced by about 20% and 23%, respectively.

Replacing oxygen with atmospheric air, the same treatment regimen of 15-watt and 6-second has about the same result as shown in Table 2.

A very mild hydrogen plasma treatment as exemplarily outlined in row 8 of Table 2 provided above did not improve film deflection meaningfully, with a 3.3% deflection reduction.

The full-size ultra-thin pellicles were subject to the same plasma treatment chamber with nitrogen as active gas. The light transmittance at 550 nm increased, going toward the opposite direction, which would reduce EUVT when compared to the untreated.

The illustrations of the embodiments described herein are intended to provide a general understanding of the various embodiments. The illustrations are not intended to serve as a complete description of all of the elements and features of products and methods that form the products or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. An extreme ultraviolet (EUV) photolithography nanotube film comprising:
a plurality of nanotubes that are intersected randomly to form an interconnected network structure in a planar orientation, the interconnected network structure
a) having a thickness ranging from a lower limit of at least 3 nm to an upper limit of at most 100 nm, and a minimum EUV transmission rate of 92%, and
b) being plasma-treated with an active gas, a treatment power, and at a treatment time interval.

2. The EUV photolithography nanotube film according to claim 1, wherein the thickness ranges from the lower limit of 3 nm to the upper limit of 40 nm.

3. The EUV photolithography nanotube film according to claim 1, wherein the thickness ranges from the lower limit of 3 nm to the upper limit of 20 nm.

4. The EUV photolithography nanotube film according to claim 1, wherein an average thickness of the interconnected network structure is between 10.7 nm and 11.9 nm.

5. The EUV photolithography nanotube film according to claim 1, wherein an EUV transmission rate rises to 95% or above.

6. The EUV photolithography nanotube film according to claim 1,
wherein the plurality of nanotubes further includes single-walled carbon nanotubes, double-walled carbon nanotubes, and multi-walled carbon nanotubes,
wherein a number of walls of single-walled carbon nanotubes is one, a number of walls of the double-walled carbon nanotubes is two, and a number of walls of the multi-walled carbon nanotubes is three or more.

7. The EUV photolithography nanotube film according to claim 6, wherein the single-walled carbon nanotubes account for a percentage between 20-40% of all nanotubes, double-walled carbon nanotubes account for a percentage 50% or higher of all nanotubes, the remaining nanotubes are multi-walled carbon nanotubes.

8. The EUV photolithography nanotube film according to claim 1, wherein the film has a free-standing portion with an area size of no less than 10 mm by 10 mm.

9. The EUV photolithography nanotube film according to claim 1, wherein the film has a free-standing portion with an area size of no less than 110 mm 140 mm.

10. A method of improving extreme ultraviolet (EUV) photolithography nanotube films, the method comprising:
obtaining a film having a plurality of carbon nanotubes that are intersected randomly to form an interconnected network structure in a planar orientation, the interconnected network structure having a thickness ranging from a lower limit of at least 3 nm to an upper limit of at most 100 nm, and a minimum EUV transmission rate of 88%, being mounted on a border with an aperture, and covering the entire aperture of the border; and
subjecting the film to a plasma treatment with an active gas, a treatment power equal to or less than 35 watts, and a treatment time interval equal to or less than 30 seconds.

11. The method according to claim 10, wherein the film has a thickness ranging from the lower limit of 3 nm to the upper limit of 40 nm.

12. The method according to claim 10, wherein the film has a thickness ranging from the lower limit of 10 nm to the upper limit of 20 nm.

13. The method according to claim 10, wherein an average thickness of the film is between 10.7 nm and 11.9 nm.

14. The method according to claim 10, wherein the active gas is oxygen, hydrogen, or atmospheric air.

15. The method according to claim 10, wherein the nanotube film has a free-standing portion with an area side of at least 10 mm by 10 mm.

16. The EUV photolithography nanotube film according to claim 1, wherein the plasma treatment power does not exceed 35 watts with a treatment time interval equal to or less than 30 seconds.

17. The method according to claim 10, wherein the nanotube film has a free-standing portion with an area size of at least 110 mm by 140 mm.

18. The method according to claim 17, wherein the plasma treatment power does not exceed 18 watts with the treatment time interval equal to or less than 10 seconds.

19. The method according to claim 17, wherein the plasma treatment power does not exceed 16 watts with the treatment time interval equal to or less than 10 seconds.

20. The method according to claim 17, wherein the active gas is oxygen gas, the treatment power is 15 watts, and the treatment time interval is 8 seconds or less.

21. The method according to claim 10, wherein the nanotubes further comprising single-walled carbon nanotubes, double-walled carbon nanotubes, and multi-walled carbon nanotubes, and wherein a number of walls included in each of the single-walled carbon nanotubes is one, a number of walls included in each of the double-walled carbon nanotubes is two, and a number of walls included in each of the multi-walled carbon nanotubes is three or more.

22. The method according to claim 21, wherein the single-walled carbon nanotubes account for a percentage between 20-40% of all carbon nanotubes, double-walled carbon nanotubes account for a percentage 50% or higher of all carbon nanotubes, and the remaining carbon nanotubes are multi-walled carbon nanotubes.
